(19) United States
(12) Patent Application Publication
(10) Pub. No.: US 2008/0188042 A1
(43) Pub. Date: Aug. 7, 2008

(54) METHOD OF MANUFACTURING THIN FILM TRANSISTOR PANEL

(75) Inventors: Byeong-Jin LEE, Yongin-si (KR); Sang-Gab KIM, Seoul (KR); Hong-Sick PARK, Suwon-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/777,769

(22) Filed: Jul. 13, 2007

(30) Foreign Application Priority Data
Oct. 2, 2006 (KR) 10-2006-0097142

(51) Int. Cl. H01L 21/84

(52) U.S. Cl. 438/158; 257/E21.7

(57) ABSTRACT

Provided is a method of manufacturing a thin film transistor panel that may reduce manufacturing costs. The method includes forming gate wires including a gate line and a gate electrode on an insulating substrate and forming data wires including source and drain electrodes, the data wires being insulated from the gate wires. The method further includes forming a passivation layer covering the gate and data wires, forming contact holes exposing the drain electrodes by etching the passivation layer, and forming a pixel electrode by depositing an indium-free transparent conductive film on the exposed drain electrode and the passivation layer and then dry etching the transparent conductive film.

### CROSS REFERENCE TO RELATED APPLICATION

This application claims priority from and the benefit of Korean Patent Application No. 10-2006-0097142, filed on Oct. 2, 2006, which is hereby incorporated by reference for all purposes as if fully set forth herein.

### BACKGROUND OF THE INVENTION

1. Field of the Invention

The present invention relates to a method of manufacturing a thin film transistor panel, and more particularly, to a method of manufacturing a thin film transistor panel that may reduce manufacturing costs.

2. Discussion of the Background

Generally, liquid crystal displays are flat panel displays that display images using liquid crystals. Liquid crystal displays are thin and light and have low power and driving voltage requirements as compared to other displays.

In a typical liquid crystal display, a liquid crystal layer is interposed between a color filter panel, where a reference electrode and a color filter are formed, and a thin film transistor substrate, where a thin film transistor and a pixel electrode are formed. The array of liquid crystal molecules is altered by applying different electric potentials to the pixel electrode and the reference electrode to form an electric field, and images are displayed by adjusting the transmission of light.

The pixel electrode is typically made of indium tin oxide (ITO) or indium zinc oxide (IZO), which are transparent conductive materials, and wet etching using a chemical solution is used to pattern the pixel electrode by photolithography. Wet etching provides for a good selection ratio and excellent etch uniformity while processing a substrate.

However, due to the depletion of indium, the cost of indium is now increasing. For this reason, there is a need for transparent conductive materials that do not include indium. However, when conventional wet etching is performed with other transparent conductive materials, the etch rate may increase and it may become difficult to achieve the desired etch shape.

### SUMMARY OF THE INVENTION

The present invention provides a method of manufacturing a thin film transistor panel that may reduce manufacturing costs.

Additional features of the invention will be set forth in the description which follows, and in part will be apparent from the description, or may be learned by practice of the invention.

The present invention discloses a method of manufacturing a thin film transistor panel. The method includes forming gate wires including a gate line and a gate electrode on an insulating substrate and forming data wires including source electrodes and drain electrodes, the data wires being insulated from the gate wires. The method further includes forming a passivation layer covering the gate wires and data wires, forming contact holes in the passivation layer to expose the drain electrodes, and depositing an indium-free transparent conductive film on the exposed drain electrodes and the passivation layer and then dry etching the transparent conductive film.

The present invention also discloses a method of manufacturing a thin film transistor panel, the method including forming a thin film transistor including a gate electrode, a source electrode, and a drain electrode on an insulating substrate, and forming a pixel electrode connected to the drain electrode by depositing an indium-free transparent conductive film and dry etching the transparent conductive film.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A is a layout view of a thin film transistor substrate manufactured by a method according to an exemplary embodiment of the invention.

FIG. 1B is a cross-sectional view taken along line B-B′ of FIG. 1A.

FIG. 2A, FIG. 3A, FIG. 4A, and FIG. 5A are layout views sequentially showing a method of manufacturing a thin film transistor substrate according to an exemplary embodiment of the invention.

FIG. 2B, FIG. 3B, FIG. 4B, and FIG. 5B are cross-sectional views taken along line B-B′ of FIG. 2A, FIG. 3A, FIG. 4A, and FIG. 5A, respectively.

FIG. 6A is a layout view of a thin film transistor substrate manufactured by a method according to another exemplary embodiment of the invention;

FIG. 6B is a cross-sectional view taken along line B-B′ of FIG. 6A;

FIG. 7A, FIG. 9A, and FIG. 15A are layout views sequentially showing a method of manufacturing a thin film transistor substrate according to another exemplary embodiment of the invention.

FIG. 7B and FIG. 8 are cross-sectional views for each process taken along line B-B′ of FIG. 7A.

FIG. 9B, FIG. 10, FIG. 11, FIG. 12, FIG. 13, and FIG. 14 are cross-sectional views for each process taken along line B-B′ of FIG. 9A.

FIG. 15B is a cross-sectional view for a process taken along line B-B′ of FIG. 15A.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as being limited to the exemplary embodiments set forth herein. Rather, these exemplary embodiments are provided so that this disclosure will be thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element, it can be directly on or directly connected to the other element or layer, or intervening elements or layers may be present. In contrast, when an element or layer is referred to as being “directly on” or “directly connected to” another element or layer, there are no intervening elements or layers present.

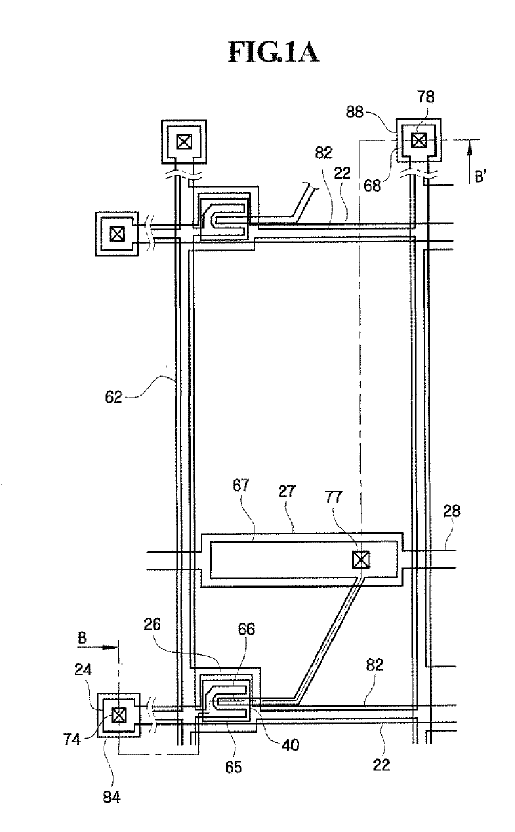

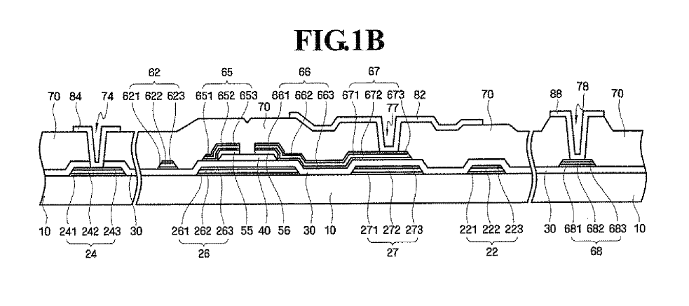

Exemplary embodiments of the invention will now be described hereafter with reference to accompanying drawings. First, referring to FIG. 1A and FIG. 1B, configuration of a thin film transistor panel manufactured by a method according to an exemplary embodiment of the invention is described below. FIG. 1A is a layout view of a thin film transistor panel manufactured by a method according to an exemplary embodiment of the invention and FIG. 1B is a cross-sectional view taken along line B-B′ of FIG. 1A.

A plurality of gate wires that transmit gate signals are formed on an insulating substrate 10. The gate wires 22, 24, 26, 27, and 28 include a gate line 22 that extends in a longitudinal direction, a gate end 24 that is connected to the end of the gate line 22 and receives gate signals from an external source and then transmits them to the gate line 22, a gate electrode 26 of a thin film transistor that protrudes from the gate line 22, and a storage electrode 27 and a storage electrode line 28 that are formed parallel to the gate line 22. The storage electrode line 28 extends in the longitudinal direction crossing a pixel region, and is connected to the storage electrode 27, which is wider than the storage electrode line 28. The storage electrode 27 overlaps a drain electrode extension 67 connected with a pixel electrode 82, which is described below, forming a storage capacitor that improves charge capacity of a pixel. The shape and arrangement of the storage electrode 27 and storage electrode line 28 may be altered in a variety of ways. Alternatively, when the sustain capacity generated by the overlap of the pixel electrode 82 and the gate line 22 is sufficient, the storage electrode 27 and storage electrode line 28 may be omitted.

The gate wires 22, 24, 26, 27, and 28 may be made of, for example, aluminum-based metals, such as aluminum (Al) and aluminum alloys, silver-based metals, such as silver (Ag) and silver alloys, copper-based metals, such as copper (Cu) and copper alloys, molybdenum-based metals, such as molybdenum (Mo) and molybdenum alloys, chromium (Cr), titanium (Ti), or tantalum (Ta). Further, the gate wires 22, 24, 26, 27, and 28 may have multi-film structures including two conductive films (not shown) that have different properties. One of the conductive films, for example, may be made of aluminum-based metal, silver-based metal, or copper-based metal having low resistivity to reduce signal delay or voltage drop of the gate wires 22, 24, 26, 27, and 28. However, the invention is not limited to the above and the conductive film may be made of a variety of metals and other conductive materials.

A gate insulating layer 30, which may be made of nitride silicon (SiNₓ) is formed on the gate wires 22, 24, 26, 27, and 28 and the substrate 10.

An island-shaped semiconductor layer 40 including a semiconductor made of hydrogenated amorphous silicon or polycrystalline silicon is formed on a gate insulating layer 30 at a location corresponding to the gate electrode 26. Ohmic contact layers 55 and 56, which may be made of silicide or n+ hydrogenated amorphous silicon with n-type impurities, such as silicide doped under high concentration, are formed on the semiconductor layer 40.

Data wires 62, 65, 66, 67, and 68 are formed on the ohmic contact layers 55 and 56 and the gate insulating layer 30. The data wires 62, 65, 66, 67, and 68 include a data line 62 that is formed lengthwise and defines a pixel by crossing the gate line 22, a source electrode 65 that protrudes from the data line 62 and extends to the upper side of the ohmic contact layer 55, a data end 68 that is connected to an end of the data line 62 and receives image signals from an external source, a drain electrode 66 that is separated from the source electrode 65 and formed on the upper side of the ohmic contact layer 56 opposite the source electrode 65 with respect to a channel portion of the thin film transistor or the gate electrode 26, and a drain electrode extension 67 having a large area that extends from the drain electrode 66 and overlaps the storage electrode 27.

The data wires 62, 65, 66, 67, and 68 may be made of, for example, aluminum-based metals, such as aluminum (Al) and aluminum alloys, silver-based metals, such as silver (Ag) and silver alloys, copper-based metals, such as copper (Cu) and copper alloys, molybdenum-based metals, such as molybdenum (Mo) and molybdenum alloys, chromium (Cr), titanium (Ti), or tantalum (Ta). Further, the data wires 62, 65, 66, 67, and 68 may have multi-film structures including two conductive films (not shown) that have physically different properties. One of the conductive films, for example, may be made of aluminum-based metal, silver-based metal, or copper-based metal having low resistivity to reduce signal delay or voltage drop of the data wires 62, 65, 66, 67, and 68.

At least a part of the source electrode 65 overlaps the semiconductor layer 40. The drain electrode 66 is opposite the source electrode 65 with respect to the gate electrode 26, and at least a part of the drain electrode 66 also overlaps the semiconductor layer 40. The ohmic contact layers 55 and 56 are disposed between the semiconductor layer 40 and the source and drain electrodes 65 and 66, respectively, and reduce contact resistance.

The drain electrode extension 67 overlaps the storage electrode 27 forming a storage capacitor with the storage electrode 27 and the gate insulating layer 30. When the storage electrode 27 is omitted, the drain extension 27 is also omitted.

A passivation layer 70 is formed on the data wires 62, 65, 66, 67, and 68 and portions on the semiconductor layer 40 without the data wires. The passivation layer 70 may be made of organic substances with excellent planarization and photosensitivity, for example, low dialectical insulating substances, such as a-Si:C:O, a-Si:O:F, formed by Plasma Enhanced Chemical Vapor Deposition (PECVD), or silicon nitride (SiNₓ) of an inorganic substance. When the passivation layer 70 is made of an organic substance, an insulating film (not shown) made of silicon nitride (SiNₓ) or silicon oxide (SiO₂) may additionally be formed to prevent the organic substance of the passivation layer 70 from contacting the exposed portion of the semiconductor layer 40 between the source electrode 65 and the drain electrode 66.

Contact holes 77 and 78 are formed through the passivation layer 70 to expose the drain electrode extension 67 and the end 68 of the data line, and a contact hole 74 is formed through the passivation layer 70 and the gate insulating layer 30 to expose the end 24 of the gate line 22. The pixel electrode 82 is formed on the passivation layer 70 and connected to the drain electrode 66 through the contact hole 77. The voltage applied to the pixel electrode 82 determines the orientation of an array of the liquid crystal molecules of a liquid crystal layer between the pixel electrode 82 and a common electrode by generating an electric field between the two electrodes.

Further, an auxiliary gate end 84 and an auxiliary data end 88, which are connected to the gate end 24 and the data end 68 through the contact holes 74 and 78, respectively, are formed on the passivation layer 70. The pixel electrode 82, the auxiliary gate end 84 and the auxiliary data end 88 may be formed of an indium-free transparent conductive film. The transparent conductive film may be made of Zinc Oxide (ZnO), Al doped ZnO (ZAO), Ga doped ZnO (ZGO), Zinc Tin Oxide (ZTO), and Fluorine doped Tin Oxide (FTO).

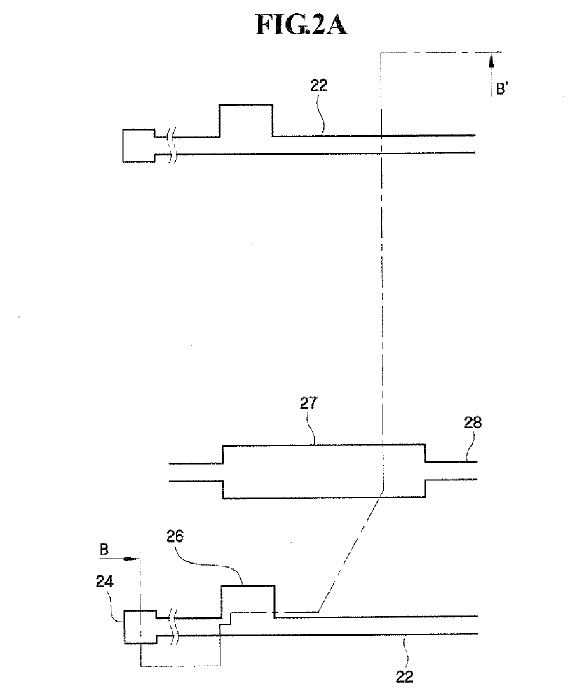

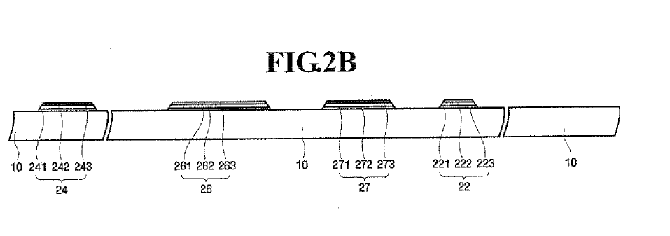

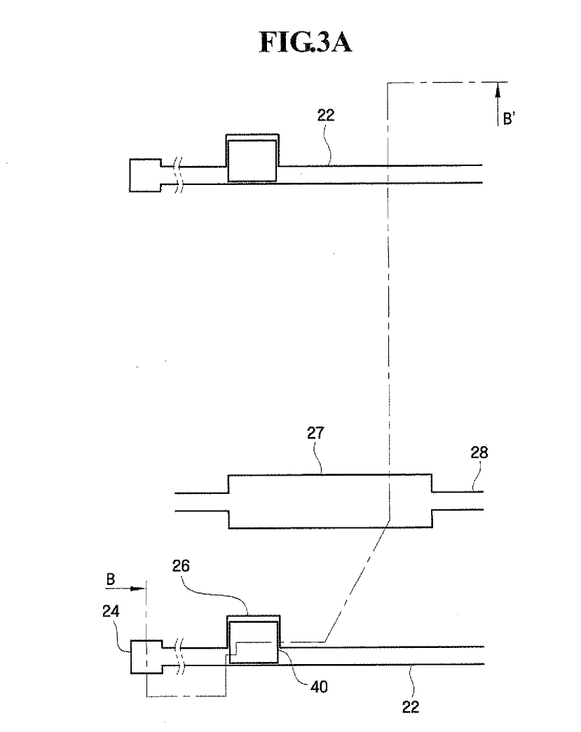

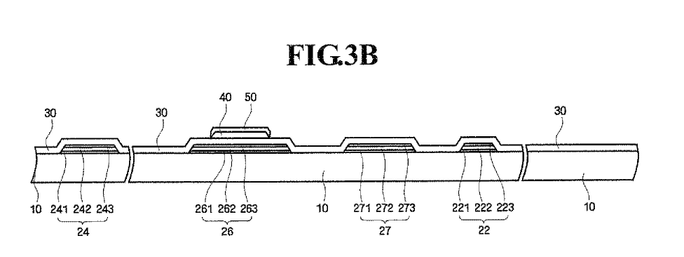

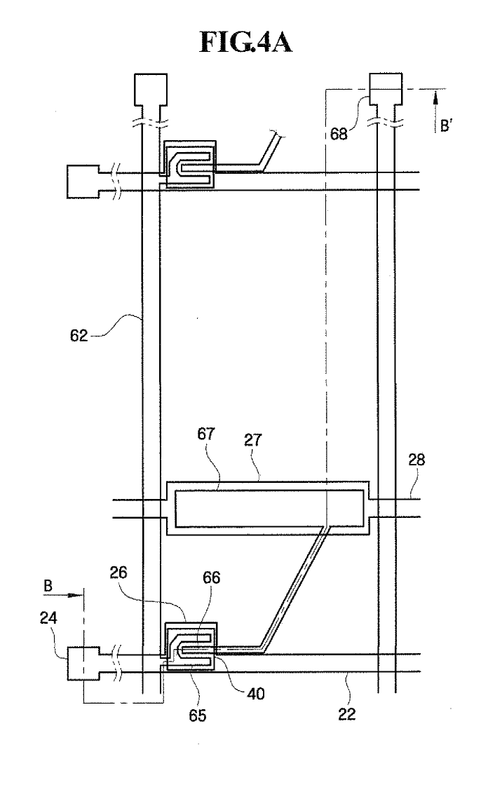

A method of manufacturing a thin film transistor substrate according to an exemplary embodiment of the invention is described below with reference to FIG. 1A, FIG. 1B, FIG. 2A, FIG. 2B, FIG. 3A, FIG. 3B, FIG. 4A, FIG. 4B, FIG. 5A, and FIG. 5B.

First, as shown in FIG. 2A and FIG. 2B, a triple gate layer, for example, molybdenum-aluminum-molybdenum, is layered on the insulating substrate 10. Photolithography is performed on the triple gate layer through dry etching with etching solution.

As a result, as shown in FIG. 2A and FIG. 2B, the gate wires 22, 24, 26, 27, and 28, including the gate line 22, gate electrode 26, gate end 24, storage electrode 27, and storage electrode line 28, are formed. As shown in FIG. 2B, each of the gate line 22, the gate electrode 26, the gate end 24, and the storage electrode 27 includes a first layer that may comprise molybdenum 221, 241, 261, 271, a second layer that may comprise aluminum 222, 242, 262, and 272, and a third layer that may comprise molybdenum 223, 243, 263, and 273.

Following the gate wires, as shown in FIG. 3A and FIG. 3B, a gate insulating layer 30 of silicon nitride, an intrinsic amorphous silicon layer, and an amorphous silicon layer with impurities doped are sequentially deposited by chemical vapor deposition and may have thicknesses in the range of 1,500 Å to 5,000 Å, 500 Å to 2,000 Å, and 300 Å to 600 Å, respectively. Subsequently, the island-shaped semiconductor layer 40 and ohmic contact layer 50 are formed on a portion of the gate insulating layer 30 corresponding to the gate electrode 26 by performing photolithography on the intrinsic amorphous silicon layer and the doped amorphous silicon layer, respectively.

Next to the island-shaped semiconductor layer 40 and ohmic contact layer 50, as shown in FIG. 4A and FIG. 4B, a triple data layer of molybdenum-aluminum-molybdenum is formed on the gate insulating layer 30, the exposed semiconductor layer 40, and the ohmic contact layer 50. Photolithography is then performed on the triple data layer through dry etching with etching solution.

Through the above process, the data wires 62, 65, 66, 67, and 68, which include the data line 62 crossing the gate line 22, the source electrode 65 connected to the data line 62 and extending to the upper side of the gate electrode 26, the data end 68 connected to an end of the data line 62, the drain electrode 66 separated from the source electrode 65 and opposite the source electrode 65 with respect to the gate electrode 26, and the drain electrode extension 67 with a wide area extending from the drain electrode 66 and overlapping the storage electrode 27, are formed. As shown in FIG. 4B, each of the data line 62, the source electrode 65, the drain electrode 66, and the drain electrode extension 67 includes a first layer that may comprise molybdenum 621, 651, 661, and 671, a second layer that may comprise aluminum 622, 652, 662, and 672, and a third layer that may comprise molybdenum 623, 653, 663, and 673.

Subsequently, the data wires 62, 65, 66, 67, and 68 are divided on the gate electrode 26 by etching the portion of the doped amorphous silicon layer (ohmic contract layer 50 in FIG. 3B) that is not covered by the data wires 62, 65, 66, 67, and 68, thereby exposing the semiconductor layer 40 between both ohmic contact layers 55 and 56. Oxygen plasma may be applied to stabilize the exposed surface of the semiconductor layer 40.

Subsequently, as shown in FIG. 5A and FIG. 5B, the passivation layer 70 is formed in the substrate. It may include a single layer or multiple layers of organic substances with excellent planarization and photosensitivity, for example, low dielectric insulating substances, such as a-Si:C:O or a-Si:O:F, formed by PECVD, or silicon nitride (SiNₓ) of an inorganic substance.

Following the passivation layer 70, the contact holes 74, 77, and 78, which expose the gate end 24, drain electrode extension 67, and the data end 68, respectively, are formed by patterning the gate insulating layer 30 and/or the passivation layer 70 through photolithography. When a photosensitive organic film is used, the contact holes may only be formed by photolithography, and it is preferable to perform photolithography with substantially the same etch rate for the gate insulating layer 30 and the passivation layer 70.

Finally, as shown in FIG. 1A and FIG. 1B, the auxiliary gate end 84 and the auxiliary data end 88 that are connected to the gate end 24 and data end 68 through the contact holes 74 and 78, respectively, and the pixel electrode 82, which is connected to the drain electrode 66 through the contact hole 77, are formed by depositing and performing photolithography on an indium-free transparent conductive film.

The transparent conductive film may be made of any one of ZnO, ZAO, ZGO, ZTO, and FTO.

Etching of the transparent conductive film may be dry etching and the etching gas may include H or Cl. For example, Cl₂, HCl, HI, and HBr may be used as etching gases. Etching gas including Cl may be used at about 1 to 200 sccm and etching gas including HBr may be used at about 1 to 200 sccm. Pressure for dry etching may be in the range of about 1 to 10 mT and source power or bias power may be in the range of about 1 to 5000 W. The source and bias power may be increased up to 3 to 4 W per unit area (cm²) of the insulating substrate 10. An etcher for dry etching may be an Inductive Coupled Plasma (ICP) or Reactive Ion Etching (RIE) etcher.

For example, the dry etching may be performed for 56 to 60 seconds with etching gas containing Cl₂ at about 3 to 7 mT pressure, about 2800 to 3200 W source power, about 1,300 to 1,700 W bias power, and about 30 to 120 sccm Cl₂.

Alternatively, the dry etching may be performed for 62 to 66 seconds with etching gas containing HBr at about 3 to 7 mT pressure, about 2,800 to 3,200 W source power, about 1,300 to 1,700 W bias power, and about 30 to 120 sccm HBr.

According to an exemplary embodiment of the invention, critical dimension skew may be reduced by performing dry etching on the transparent conductive film and forming the pixel electrode. This is because wet etching is isotropic etching in which an object is etched at the same rate in the vertical direction and the horizontal direction, making it difficult to achieve a desired etched shape and resulting in a large critical dimension skew. Conversely, dry etching is an anisotropic etching in which physical action, due to ion impact to the surface of the substrate or chemical action of reactant substances created in plasma, is created, or physical and chemical action is simultaneously created, so that it may be easier to control the etch rate and reduce the critical dimension skew. Accordingly, dry etching may be more effective than wet etching in forming a pixel electrode.

Further, according to an exemplary embodiment of the invention, a transparent conductive film that does not contain indium is used as a pixel electrode and therefore, manufacturing costs may be reduced.

Although the present invention discloses a method of manufacturing a thin film transistor substrate in which a semiconductor layer and data wires are formed by photolithography using different masks as described above, it is also applicable to a method of manufacturing a thin film transistor substrate in which a semiconductor layer and data wires are formed by photolithography using one photosensitive pattern, which is now described below with reference to accompanying drawings.

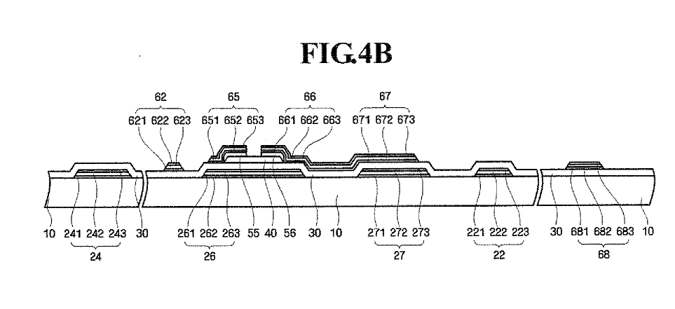

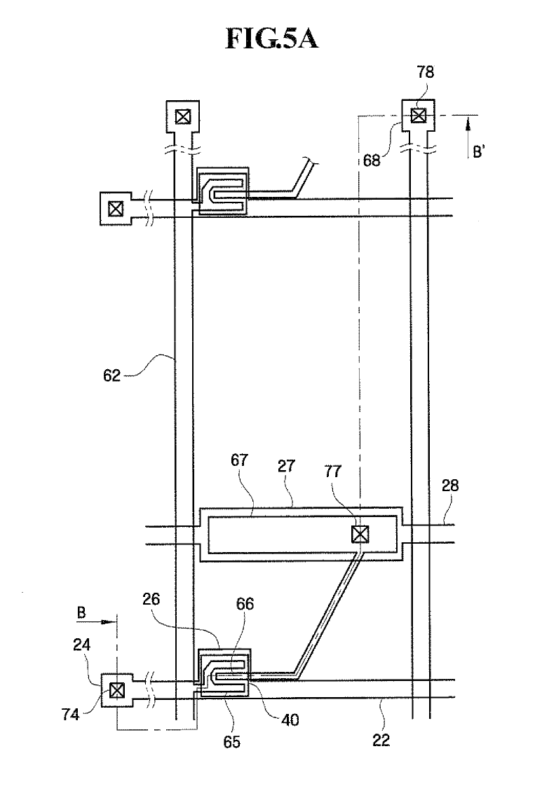

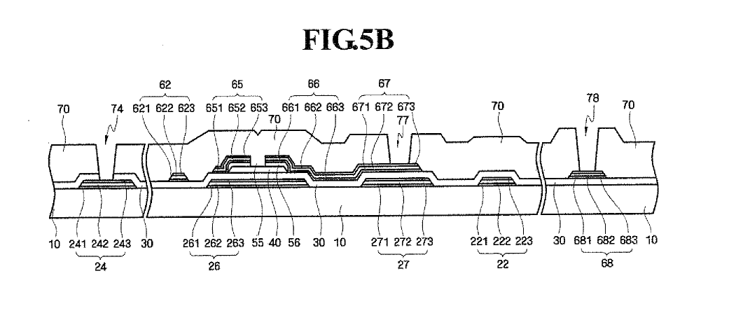

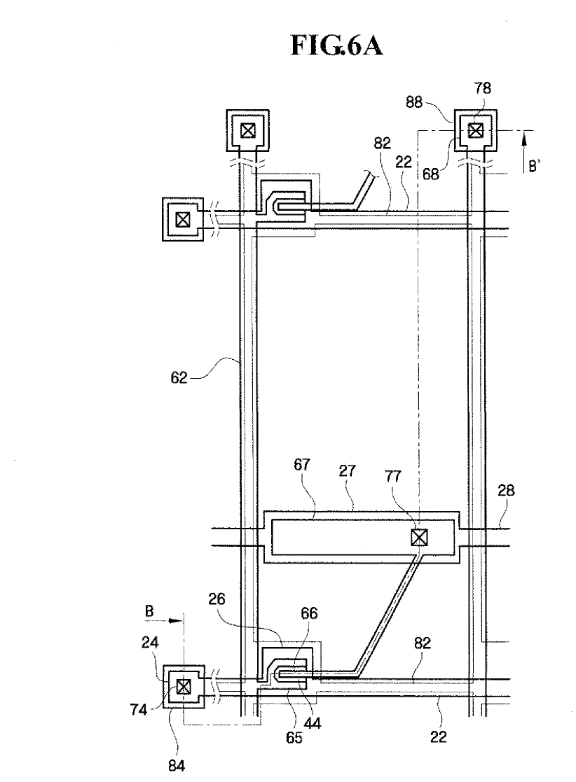

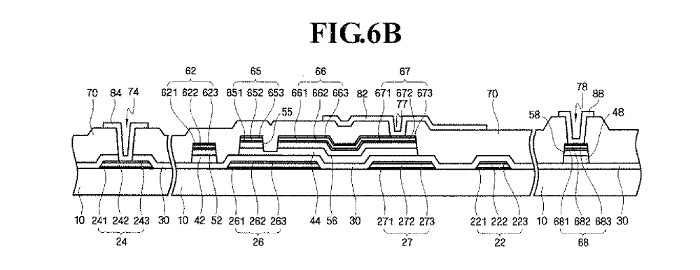

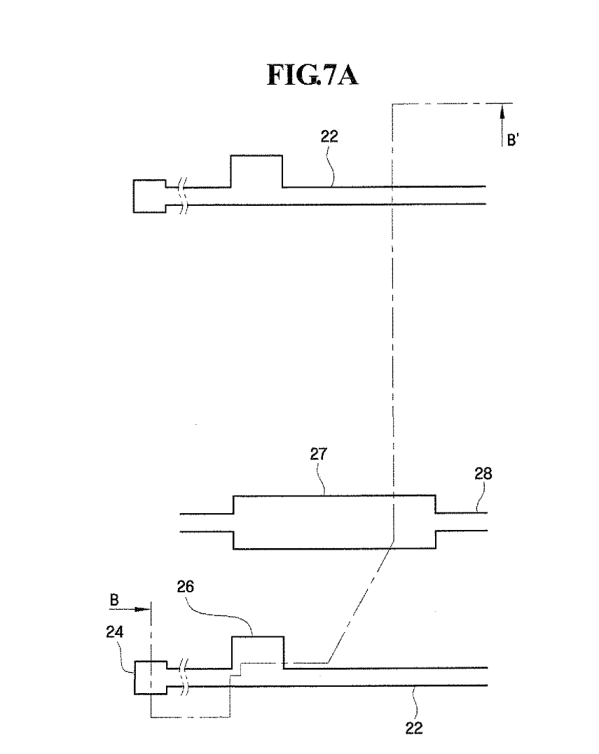

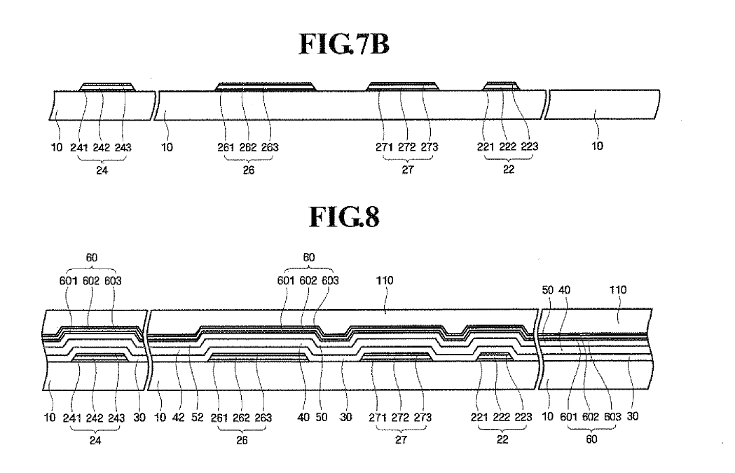

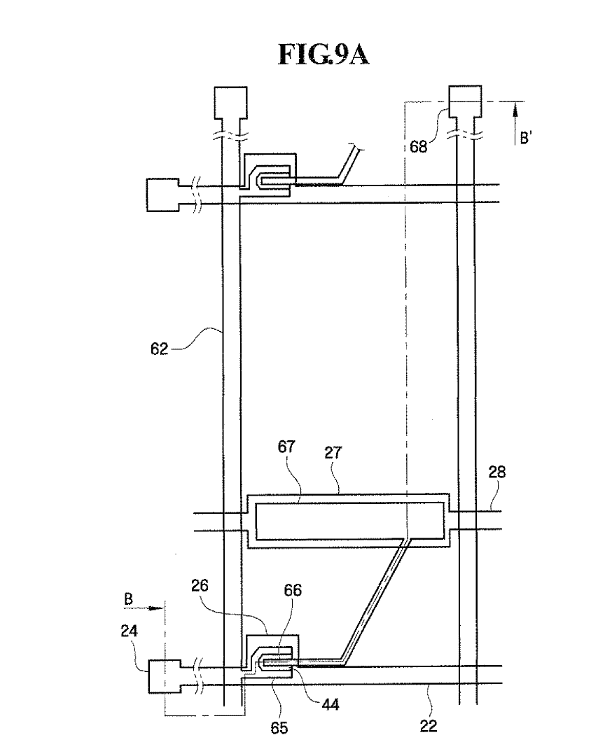

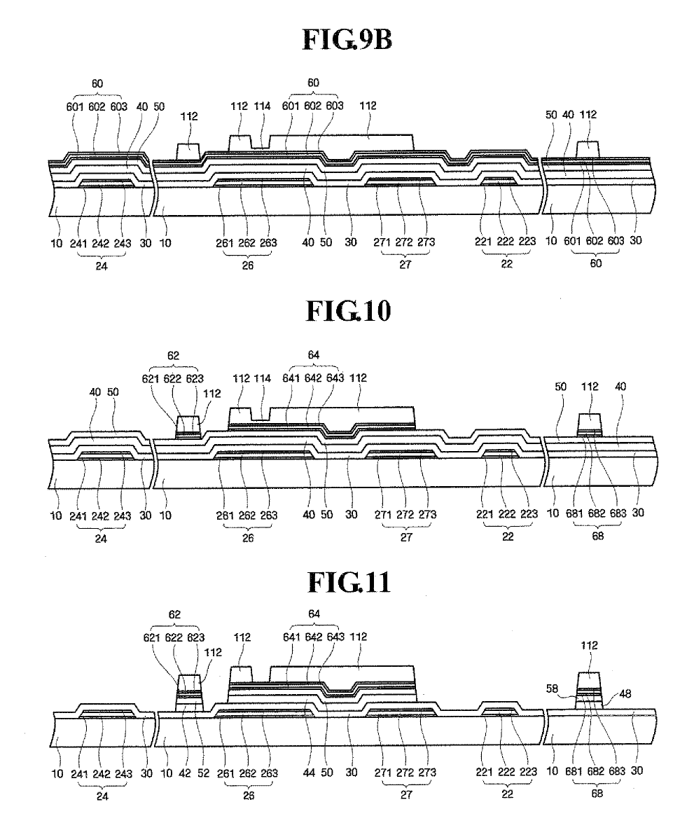

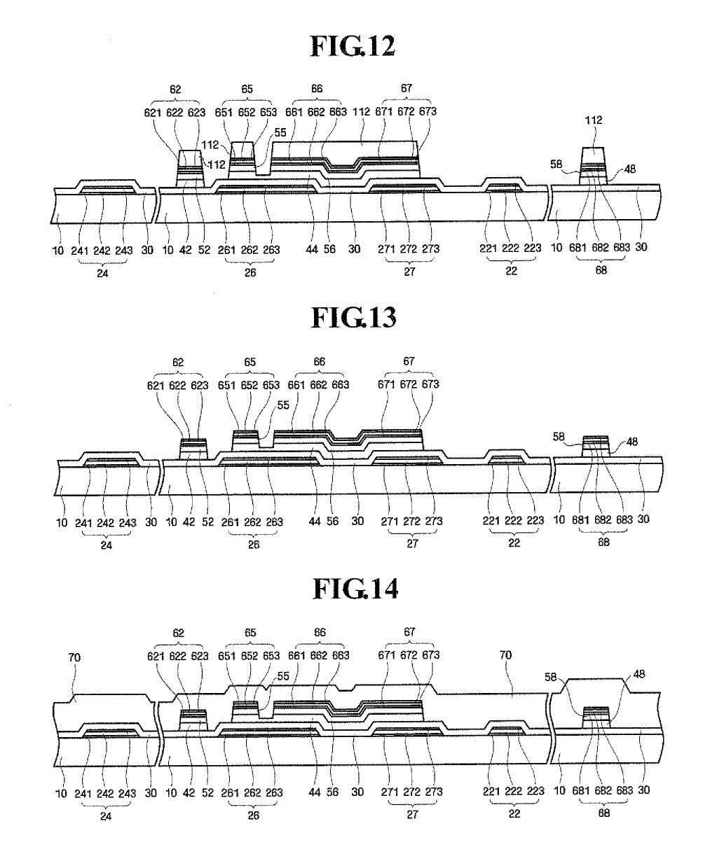

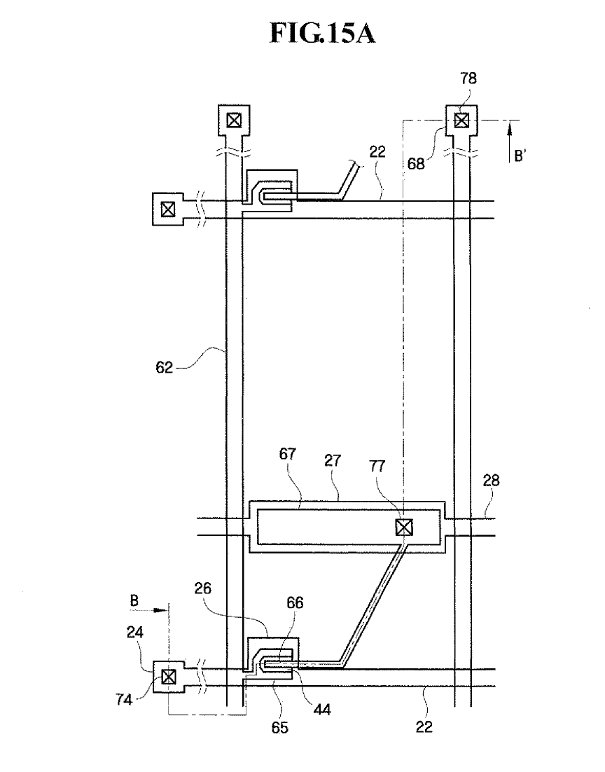

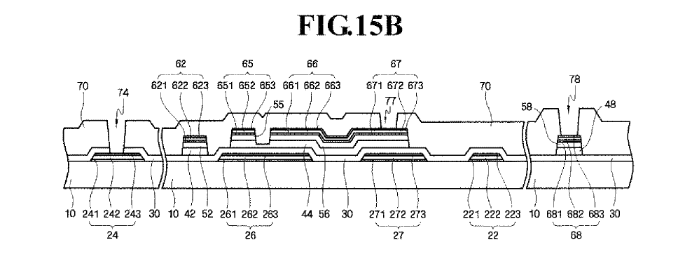

First of all, the configuration of a unit pixel of a thin film transistor panel manufactured by a method according to another exemplary embodiment of the invention is described with reference to FIG. 6A, FIG. 6B, FIG. 7A, FIG. 7B, FIG. 8, FIG. 9A, FIG. 9B, FIG. 10, FIG. 11, FIG. 12, FIG. 13, FIG. 14, FIG. 15A, and FIG. 15B.

FIG. 6A is a layout view of a thin film transistor panel manufactured by a method according to another exemplary embodiment of the invention and FIG. 6B is a cross-sectional view taken along line B-B′ of FIG. 6A.

Similarly to the first embodiment, a plurality of gate wires that transmit gate signals are formed on an insulating substrate 10. The gate wires 22, 24, 26, 27, and 28 include a gate line 22 that extends in the longitudinal direction, a gate end 24 that is connected to the end of the gate line 22 and receives gate signals from an external source and then transmits them to the gate line 22, a gate electrode 26 of a thin film transistor that protrudes so as to connect to the gate line 22, and a storage electrode 27 and a storage electrode line 28 that are formed parallel to the gate line 22. The storage electrode line 28 extends in the longitudinal direction crossing a pixel region, and is connected to the storage electrode 27, which is wider than the storage electrode line 28. The storage electrode 27 overlaps a drain electrode extension 67 connected to a pixel electrode 82, to be described below, forming a storage capacitor that improves charge capacity of a pixel. The shape and arrangement of the storage electrode 27 and storage electrode line 28 may be altered in a variety of ways. Alternatively, when sustain capacity generated by the overlap of the pixel electrode 82 and the gate line 22 is sufficient, the storage electrode 27 and the storage electrode line 28 may be omitted.

A gate insulating layer 30, which may be made of silicon nitride (SiNₓ), is formed on the gate wires 22, 24, 26, 27, and 28 and the substrate 10.

Semiconductor patterns 42, 44, and 48 formed of a semiconductor made of hydrogenated amorphous silicon or polycrystalline silicon are formed on the gate insulating layer 30. Ohmic contact layers 52, 55, 56, and 58 made of n+ hydrogenated amorphous silicon with n-type impurities, such as silicide, doped under high concentration are formed on the semiconductor patterns 42, 44, and 48.

Data wires 62, 65, 66, 67, and 68 are formed on the ohmic contact layers 52, 55, 56, and 58. The data wires 62, 65, 66, 67, and 68 include a data line 62 formed lengthwise and defining a pixel by crossing the gate line 22, a source electrode 65 protruding from the data line 62 and extending to the upper side of the ohmic contact layer 55, a data end 68 connected to an end of the data line 62 to receive image signals from an external source, a drain electrode 66 separated from the source electrode 65 and formed on the upper side of the ohmic contact layer 56 opposite the source electrode 65 with respect to a channel portion of the thin film transistor or the gate electrode 26, and a drain electrode extension 67 with a large area extending from the drain electrode 66 and overlapping the storage electrode 27.

At least a part of the source electrode 65 overlaps the semiconductor layer 40. The drain electrode 66 is opposite the source electrode 65 with respect to the gate electrode 26 and at least a part of the drain electrode 66 also overlaps the semiconductor layer 40. The ohmic contact layers 55 and 56 are disposed between the semiconductor layer 40 and the source and drain electrodes 65 and 66, respectively, and may reduce contact resistance.

The drain electrode extension 67 overlaps the storage electrode 27 forming a storage capacitor with the storage electrode 27 and the gate insulating layer 30. When the storage electrode 27 is omitted, the drain extension 67 is also omitted.

The ohmic contact layers 52, 55, 56, and 58 reduce contact resistance of the semiconductor patterns 42, 44, and 48 and the data wires 62, 65, 66, 67, and 68 and have the same shape as the data wires 62, 65, 66, 67, and 68.

On the other hand, the semiconductor patterns 42, 44, and 48, except for at the channel portion of the thin film transistor, have the same shape as the data wires 62, 65, 66, 67, and 68 and contact layers 52, 55, 56, and 58. That is, at the channel portion of the thin film transistor, the source electrode 65 and the drain electrode 66 are separated and the ohmic contact layer 55 under the source electrode 65 and the ohmic contact layer 56 under the drain electrode 66 are also separated, but the semiconductor pattern 44 for the thin film transistor is not cut and continues, thereby forming the channel of the thin film transistor.

A passivation layer 70 is formed on the data wires 62, 65, 66, 67, and 68 and portions on the semiconductor pattern 44 without the data wires.

Contact holes 77 and 78 are formed through the passivation layer 70 to expose the drain electrode extension 67 and the end 68 of the data line, and a contact hole 74 is formed through the passivation layer 70 and the gate insulating layer 30 to expose the end 24 of the gate line 22.

Further, an auxiliary gate end 84 and an auxiliary data end 88 connected to the gate end 24 and the data end 68 through the contact holes 74 and 78, respectively, are formed on the passivation layer 70. The pixel electrode 82, the auxiliary gate end 84 and the auxiliary data end 88 may be formed of an indium-free transparent conductive film. The transparent conductive film may be made of any one of ZnO, ZAO, ZGO, ZTO, and FTO.

A method of manufacturing a thin film transistor substrate according to another exemplary embodiment of the invention is now described in detail hereafter with reference to FIG. 6A, FIG. 6B, FIG. 7A, FIG. 7B, FIG. 8, FIG. 9A, FIG. 9B, FIG. 10, FIG. 11, FIG. 12, FIG. 13, FIG. 14, FIG. 15A, and FIG. 15B.

First, as shown in FIG. 7A and FIG. 7B, similarly to FIG. 2A and FIG. 2B, a triple gate layer of, for example, lower molybdenum 601-aluminum 602-upper molybdenum 603 is layered on the substrate 10. Photolithography is then performed on the triple gate layer.

As a result, as shown in FIG. 7A and FIG. 7B, the gate wires 22, 24, 26, 27, and 28, including the gate line 22, gate electrode 26, gate end 24, storage electrode 27, and storage electrode line 28, are formed.

Subsequently, as shown in FIG. 8, the gate insulating layer 30, an intrinsic amorphous silicon layer 40, and a doped amorphous silicon layer 50 are sequentially deposited. After the deposition, a triple data layer 60 of lower molybdenum-aluminum-upper molybdenum is layered on the doped amorphous silicon layer 50 and then photolithography is performed on the triple data layer 60.

A photosensitive film 110 is applied onto the triple data layer 60.

Referring to FIG. 9A, FIG. 9B, FIG. 10, FIG. 11, FIG. 12, FIG. 13, and FIG. 14, photosensitive film patterns 112 and 114 are formed, as shown in FIG. 9B, by irradiating light to the photosensitive film 110 through a mask and developing it. As for the photosensitive film patterns 112 and 114, the photosensitive film pattern 114 at the channel portion of the thin film transistor, i.e. between the source electrode 65 and the drain electrode 66, is thinner than the photosensitive film pattern 112 at the data wire portion, i.e. the portion where the data wires are formed, and the rest of the photosensitive film. The thickness ratio of the photosensitive film pattern 114 remaining at the channel portion and the photosensitive film pattern 112 remaining at the data wire portion depends on the processing conditions during etching, to be described below, but the thickness of the photosensitive film pattern 114 may be about ½ of that of the photosensitive film pattern 112, for example, 4000 Å.

As described above, a variety of methods of altering the thicknesses of the photosensitive film patterns may be used. For example, a latticed pattern may be formed or a translucent film may be used to adjust the transmitting quantity of light.

Subsequently, etching is performed on the photosensitive film pattern 114 and the triple data layer 60 of the upper molybdenum film 603, aluminum film 602, and lower molybdenum film 601 under the photosensitive film pattern 114. The etching is substantially the same as for the data wires in the exemplary embodiment of FIG. 1A, FIG. 1B, FIG. 2A, FIG. 2B, FIG. 3A, FIG. 3B, FIG. 4A, FIG. 4B, FIG. 5A, and FIG. 5B and for the gate wires 22, 24, 26, 27, and 28 in the present exemplary embodiment, and therefore, is not repeatedly described.

Accordingly, as shown in FIG. 10, only the triple layer patterns 62, 64, 67, and 68 at the channel portion and the data wire portion remain and the rest of the triple layer 60 is removed, so that the doped amorphous silicon layer 50 is exposed. The triple layer patterns 62, 64, 67, and 68 have the same shape as the data wires 62, 65, 66, 67, and 68 of the first embodiment, except that the source and drain electrodes 65 and 66 are not separated, but rather, are connected.

Following the above-mentioned etching, as shown in FIG. 11, the doped amorphous silicon layer 50, exposed at portions other than the channel and data wire portions, and the intrinsic amorphous silicon layer 40 are removed simultaneously by dry etching with the photosensitive film pattern 114. The aforementioned etching should be performed under conditions that permit only the photosensitive film patterns 112 and 114, the doped amorphous silicon layer 50, and the intrinsic amorphous silicon layer 40 to be etched simultaneously, and the gate insulating layer 30 not to be etched. The etching may be performed under conditions that result in etch rates for the photosensitive film patterns 112 and 114 and the intrinsic amorphous silicon layer 40 that are almost the same.

As a result, as shown in FIG. 11, the photosensitive film pattern 114 of the channel portion is removed and the triple layer pattern 64 for the source and drain electrodes 65 and 66 is exposed accordingly. The doped amorphous silicon layer 50 and the intrinsic amorphous silicon layer 40 at other portions are removed and the gate insulating layer 30 is correspondingly exposed. The photosensitive film pattern 112 at the data wire portion may also be etched and the total thickness may be reduced.

Subsequently, the remaining photosensitive film on the surface of the triple layer pattern 64 for the source and drain electrodes 65 and 66 at the channel portion is removed by ashing.

As an alternative to ashing, as shown in FIG. 11, the triple layer pattern 64 of the upper molybdenum film 643, aluminum film 642, and lower molybdenum film 641 at the channel portion may be removed by etching.

After the above etching, the ohmic contact layer 57 of doped amorphous silicon is etched, for example, through dry etching. In etching, the total thickness may be reduced due to the removal of the semiconductor pattern 44 and the photosensitive film pattern 112 may be etched to a predetermined thickness. The above etching should be performed under conditions that do not permit the gate insulating layer 30 to be etched, and the photosensitive film pattern should be sufficiently thick so that the data wires 62, 65, 66, 67, and 68 are not exposed due to the etching of the photosensitive film portion 112.

Through the above etching, while the source electrode 65 and the drain electrode 66 are separated, the ohmic contact layers 55 and 56 under the data wires 65 and 66 are completed.

Subsequently, the photosensitive film pattern 112 remaining on the data wire portion is removed as shown in FIG. 13.

Subsequently, the passivation layer 70 is formed as shown in FIG. 14.

Following the passivation layer 70, as shown in FIG. 15A and FIG. 15B, the contact holes 77, 74, and 78 to expose the drain electrode extension 67, gate end 24, and data end 68, respectively, are formed by etching the passivation layer 70 and/or the gate insulating layer 30.

Finally, as shown in FIG. 6A and FIG. 6B, the pixel electrode 82 connected to the drain electrode extension 67, the auxiliary gate end 84 connected to the gate end 24, and the auxiliary data end 88 connected to the data end 68 are formed by performing photolithography through etching on an indium-free transparent conductive film having a thickness of 400 Å to 500 Å.

The transparent conductive film may be made of any one of ZnO, ZAO, ZGO, ZTO, and FTO.

Etching of the transparent conductive film may be dry etching and the etching gas may include H or Cl. For example, Cl₂, HCl, HI, and HBr may be used as etching gases. Etching gas including Cl may be used at about 1 to 200 sccm and etching gas including HBr may be used at about 1 to 200 sccm. Pressure for dry etching may be in the range of about 1 to 10 mT and source power or bias power may be in the range of about 1 to 5,000 W.

Dry etching may be performed for 56 to 60 seconds with etching gas containing Cl₂ at about 3 to 7 mT pressure, about 2,800 to 3,200 W source power, about 1,300 to 1,700 W bias power, and about 30 to 120 sccm Cl₂.

Alternatively, dry etching may be performed for 62 to 66 seconds with etching gas containing HBr at about 3 to 7 mT pressure, about 2,800 to 3,200 W source power, about 1,300 to 1,700 W bias power, and about 30 to 120 sccm HBr.

Nitrogen gas may be used for pre-heating before the transparent conductive film is layered to prevent a metal oxide film from being created on the metal film 24, 67, and 68 exposed by the contact holes 74, 77, and 78.

According to the above exemplary embodiment, not only may the effects of the first exemplary embodiment be obtained, but the manufacturing process may be simplified, because the data wires 62, 65, 66, 67, and 68, the ohmic contact layers 52, 55, 56, and 58, and the semiconductor patterns 42 and 48 are formed using one mask, and while they are formed, the source electrode 65 and the drain electrode 66 are separated.

As described above, a method of manufacturing a thin film transistor panel according to the present invention may reduce critical dimension skew because a pixel electrode is formed by performing dry etching on a transparent conductive film that does not contain indium.

Further, manufacturing costs may be reduced because a transparent conductive film that does not contain indium may be used as a pixel electrode.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A method of manufacturing a thin film transistor panel, the method comprising:
forming gate wires comprising a gate line and a gate electrode on an insulating substrate;
forming data wires comprising source electrodes and drain electrodes, the data wires being insulated from the gate wires;
forming a passivation layer covering the gate wires and the data wires;
forming contact holes in the passivation layer to expose the drain electrodes; and
depositing an indium-free transparent conductive film on the exposed drain electrodes and the passivation layer and then dry etching the transparent conductive film.

2. The method of claim 1, wherein the transparent conductive film is made of one of Zinc Oxide (ZnO), Al doped ZnO (ZAO), Ga doped ZnO (ZGO), Zinc Tin Oxide (ZTO), and Fluorine doped Tin Oxide (FTO).

3. The method of claim 1, wherein the dry etching uses etching gas comprising H or Cl.

4. The method of claim 3, wherein the dry etching is performed at a pressure of about 1 to 10 mT.

5. The method of claim 3, wherein the dry etching is performed at a source power or a bias power of about 1 to 5,000 W.

6. The method of claim 5, wherein the source power or the bias power increases at about 3 to 4 W per unit area (cm²) of the insulating substrate.

7. The method of claim 3, wherein the etching gas comprises Cl and has a flow rate ranging from about 1 to 200 sccm.

8. The method of claim 3, wherein the etching gas comprises HBr and has a flow rate ranging from about 1 to 200 sccm.

9. The method of claim 3, wherein the dry etching is performed for 56 to 60 seconds with etching gas comprising Cl₂ at about 3 to 7 mT pressure, about 2,800 to 3,200 W source power, about 1,300 to 1,700 W bias power, and about 30 to 120 sccm.

10. The method of claim 3, wherein the dry etching is performed for 62 to 66 seconds with etching gas comprising HBr at about 3 to 7 mT pressure, about 2,800 to 3,200 W source power, about 1,300 to 1,700 W bias power, and about 30 to 120 sccm.

11. The method of claim 1, further comprising:
forming a semiconductor layer overlapping the gate wires and the data wires.

12. The method of claim 11, wherein the semiconductor layer and the data wires are formed by photolithography using only one photosensitive film pattern.

13. A method of manufacturing a thin film transistor panel, the method comprising:
forming a thin film transistor comprising a gate electrode, a source electrode, and a drain electrode on an insulating substrate; and
forming a pixel electrode connected to the drain electrode by depositing an indium-free transparent conductive film and dry etching the transparent conductive film.

14. The method of claim 13, wherein the transparent conductive film is made of one selected from the group consisting of Zinc Oxide (ZnO), Al doped ZnO (ZAO), Ga doped ZnO (ZGO), Zinc Tin Oxide (ZTO), and Fluorine doped Tin Oxide (FTO).

15. The method of claim 13, wherein the dry etching uses etching gas comprising H or Cl.

16. The method of claim 15, wherein the dry etching is performed at a pressure of about 1 to 10 mT.

17. The method of claim 15, wherein the dry etching is performed at a source power or a bias power of about 1 to 5,000W.

18. The method of claim 17, wherein the source power or the bias power increases at about 3 to 4W per unit area (cm²) of the insulating substrate.

19. The method of claim 15, wherein the etching gas comprises Cl and has a flow rate of about 1 to 200 sccm.

20. The method of claim 15, wherein the etching gas comprises HBr and has a flow rate of about 1 to 200 sccm.
